(19) United States
(12) Patent Application Publication
(10) Pub. No.: US 2023/0058681 A1
(43) Pub. Date: Feb. 23, 2023

(54) PRINTED DEVICES IN CAVITIES

(71) Applicant: X-Celeprint Limited, Dublin (IE)

(72) Inventors: António José Marques Trindade, Cork (IE); Ronald S. Cok, Rochester, NY (US)

(21) Appl. No.: 17/404,300

(22) Filed: Aug. 17, 2021

(51) Int. Cl. H01L 23/00; H01L 23/13; H01L 21/683; H01L 25/065

(52) U.S. Cl. CPC H01L 24/20; H01L 21/6835; H01L 23/13; H01L 24/19; H01L 25/0655; H01L 2224/211; H01L 2224/2101; H01L 2224/2105

(57) ABSTRACT

A micro-device structure includes a substrate having a substrate surface and a substrate contact disposed on or in the substrate surface, a cavity extending into the substrate from the substrate surface, a micro-device disposed in the cavity, the micro-device comprising a micro-device contact, a planarization layer disposed over at least a portion of the substrate, and an electrode disposed at least partially over or on the planarization layer and electrically connected to the micro-device contact.

### TECHNICAL FIELD

The present disclosure generally relates to the micro-assembly and electrical connection of micro-integrated circuits using micro-transfer printing.

### BACKGROUND

Components can be transferred from a source wafer to a target substrate using micro-transfer printing. Methods for transferring small, active components (e.g., micro-devices) from one substrate to another are described in U.S. Pat. No. 7,943,491, U.S. Pat. No. 8,039,847, and U.S. Pat. No. 7,622,367. In these approaches, small integrated circuits are formed on a native semiconductor source wafer. The small, unpackaged bare-die integrated circuits, or chiplets, are released from the native source wafer by pattern-wise etching sacrificial portions of a sacrificial layer located beneath the chiplets, leaving each chiplet suspended over an etched sacrificial portion by a tether physically connecting the chiplet to an anchor separating the etched sacrificial layer portions. A viscoelastic stamp is pressed against the process side of the chiplets on the native source wafer, adhering each chiplet to an individual stamp post. The stamp with the adhered chiplets is then removed from the native source wafer. The chiplets on the stamp posts are pressed against a non-native target substrate or backplane with the stamp and adhered to the target substrate. In another example, U.S. Patent No. 8,722,458 entitled Optical Systems Fabricated by Printing-Based Assembly teaches transferring light-emitting, light-sensing, or light-collecting semiconductor elements from a wafer substrate to a target substrate or backplane.

Electrically connecting integrated circuit structures on a wafer or other substrate can be difficult if the integrated circuit structures extend a significant height above the substrate. This height is commonly called a step height and can be, for example, no less than two microns, no less than five microns, no less than ten microns, or no less than twenty microns. Electrical connections to integrated circuit structures are commonly made on the top (e.g., the process surface) of an integrated circuit structure. When conductive materials, for example metals used to make electrodes or electrical wires, are deposited on a substrate, for example by evaporation or sputtering, the materials tend to deposit more thickly on horizontal surfaces (e.g., the substrate surface or micro-device top surface) than on vertical surfaces (e.g., the side of an integrated circuit or micro-device structure) causing relatively poor, or no, electrical conductivity on the vertical surface. This problem becomes more significant as the step height increases. Conventionally, this problem is addressed by making a more gradual transition from a substrate surface to the top of the integrated circuit structure so that conductive material deposits thicker on the gradual transition. For example, dielectric materials can be deposited and patterned with sloped walls. However, this approach makes the connected structure larger, inhibiting desirable miniaturization. Another method relies on planarizing the substrate surface so that the substrate surface is approximately in the same plane, or even slightly above, a top surface of the integrated circuit structure. This approach is described in, for example, U.S. 5,674,773 entitled Method for planarizing high step-height integrated circuit structures. However, a thick planarization layer can inhibit forming electrical connections to a metal layer, contact pad, or conductor (wire) on the substrate surface, since vias will be necessary to open the electrical connections and the side walls of the vias can suffer from the same step height problem.

There is a need, therefore, for integrated-circuit structures and methods that facilitate electrical connections between the integrated-circuit structures.

### SUMMARY

The present disclosure provides, inter alia, structures and methods for a micro-device structure that includes a substrate having a substrate surface, a cavity disposed in and extending into the substrate from the substrate surface, a micro-device disposed in the cavity, the micro-device comprising a micro-device contact, a planarization layer disposed over at least a portion of the substrate, and an electrode disposed at least partially over or on the planarization layer and electrically connected to the micro-device contact.

According to some embodiments, the micro-device structure comprises a substrate contact disposed on or in the substrate surface and the electrode is electrically connected to the substrate contact. The substrate contact can be an electrode, wire, contact pad or other electrically conductive structure disposed on the substrate. The micro-device can comprise a separated or broken (e.g., fractured) tether as a consequence of micro-transfer printing the micro-device from a micro-device source wafer into the cavity in the substrate. The planarization layer can be disposed at least partly in the cavity and the micro-device can be disposed at least partly on at least a portion of the planarization layer in the cavity.

According to some embodiments, (i) the micro-device has a thickness no greater than two microns, no greater than five microns, no greater than ten microns, no greater than fifteen microns, or no greater than twenty microns, (ii) the cavity has a depth of no greater than 500 nm, no greater than one micron, no greater than two microns, no greater than five microns, no greater than ten microns, no greater than fifteen microns, or no greater than twenty microns, (iii) the planarization layer has a thickness over the substrate surface of no greater than ten nm, no greater than twenty nm, no greater than thirty nm, no greater than fifty nm, no greater than sixty nm, no greater than seventy-five nm, no greater than one hundred nm, no greater than two hundred fifty nm, no v than five hundred nm, or no greater than one micron, or (iv) any compatible combination of (i), (ii), and (iii).

The substrate surface and a top surface of the micro-device can be separated by a distance no greater than five microns, no greater than three microns, no greater than two microns, no greater than one micron, or no greater than five hundred nm in a direction orthogonal to the substrate surface.

According to some embodiments of the present disclosure, the micro-device is a first micro-device, the micro-device contact is a first micro-device contact and the micro-device structure comprises a second micro-device disposed in the cavity, the second micro-device comprising a second micro-device contact, and the electrode electrically connects the first micro-device contact to the second micro-device contact.

According to some embodiments, the substrate surface and a top surface of the micro-device are separated by a distance less than a thickness of the micro-device (e.g., no more than half of the thickness, no more than a quarter of the thickness, no more than an eighth of the thickness, or no more than a tenth of the thickness).

According to some embodiments of the present disclosure, the micro-device is a first micro-device, the micro-device contact is a first micro-device contact, the cavity is a first cavity, and the micro-device structure comprises a second micro-device disposed in a second cavity extending into the substrate from the substrate surface, the second micro-device comprising a second micro-device contact, and the electrode electrically connects the first micro-device contact to the second micro-device contact.

According to some embodiments of the present disclosure, a micro-device structure comprises a substrate having a substrate surface, one or more cavities extending into the substrate from the substrate surface, two or more micro-devices, at least one of the micro-devices disposed in each of the one or more cavities, each of the micro-devices comprising a micro-device contact, and an electrode electrically connecting at least a first micro-device contact of a first one of the micro-devices and a second micro-device contact of a second one of the micro-devices. The one or more cavities can comprise at least two cavities, two or more of the micro-devices are disposed in one of the one or more cavities, or both. According to some embodiments, a planarization layer is disposed over at least a portion of the substrate. According to some embodiments, a first cavity of the one or more cavities extends a first distance into the substrate, a second cavity of the one or more cavities extends a second distance into the substrate, and the first distance is different from the second distance. According to some embodiments, a first micro-device of the two or more micro-devices has a first thickness, a second micro-device of the two or more micro-devices has a second thickness, and the first thickness is different from the second thickness. Some embodiments of the present disclosure comprise a substrate contact disposed on or in the substrate surface and the electrode is electrically connected to the substrate contact.

According to some embodiments, a top surface of the micro-device is separated from the substrate surface by a distance no greater than five microns, no greater than three microns, no greater than two microns, no greater than one micron, or no greater than five hundred nm in a direction orthogonal to the substrate surface. According to some embodiments, the micro-device comprises a separated or fractured tether.

According to embodiments of the present invention, ones of the micro-devices (i) have different functionalities, (ii) comprise different materials (e.g., different semiconductors) (e.g., have been printed from different source wafers), or (iii) both (i) and (ii). Some embodiments further comprise a second electrode electrically connecting at least a third micro-device contact of a third one of the micro-devices and a fourth micro-device contact of a fourth one of the micro-devices. The electrode can further electrically connect at least a third micro-device contact of a third one of the micro-devices.

According to some embodiments of the present disclosure, a method of making a micro-device structure comprises providing a substrate having a substrate surface and one or more cavities extending into the substrate from the substrate surface, providing a micro-device source wafer comprising one or more micro-devices disposed on or in the micro-device source wafer, each comprising a micro-device contact, micro-transfer printing the one or more micro-devices from the micro-device source wafer into the one or more cavities, planarizing the substrate, and forming an electrode disposed at least partially over or on the planarization layer that electrically connects to the micro-device contact of at least one of the micro-devices. Some embodiments comprise forming one or more vias in the planarizing layer prior to forming the electrode and forming the electrode comprises forming a portion of the electrode in the via. The one or more vias can have sloped sides. Forming the electrode can comprise forming one or electrodes on the substrate surface or in electrical contact with a substrate contact disposed on the substrate surface. The at least one of the micro-devices can be at least two of the micro-devices. The substrate can comprise a substrate contact disposed on or in the substrate surface and forming the electrode can comprise electrically connecting the electrode to the substrate contact.

Embodiments of the present disclosure provide improved electrical connections between the micro-device contacts on a top surface of a micro-device disposed on a substrate and substrate contacts or electrical connections on the substrate or a layer disposed on the substrate.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1A is a cross section according to illustrative embodiments of the present disclosure;

FIG. 1B is a plan view excluding the planarization layer with a cross section line A corresponding to FIG. 1A according to illustrative embodiments of the present disclosure;

FIG. 1C is a perspective micro-graph according to illustrative embodiments of the present disclosure;

FIG. 1D is a plan view micro-graph according to illustrative embodiments of the present disclosure;

FIG. 2 is a flow diagram according to illustrative embodiments of the present disclosure;

FIGS. 3A-3F are successive cross sections showing steps in constructing a micro-device structure according to illustrative embodiments of the present disclosure;

FIGS. 4-5 are cross sections showing cavities of various depths according to illustrative embodiments of the present disclosure;

FIG. 6 is a cross section wherein the planarization layer is disposed only in the cavity according to illustrative embodiments of the present disclosure;

FIG. 7 is a cross section wherein the planarization layer is not disposed over the micro-device according to illustrative embodiments of the present disclosure;

FIG. 8 is a cross section wherein the planarization layer is disposed at least partially beneath the micro-device according to illustrative embodiments of the present disclosure;

FIG. 9 is a partial plan view excluding the planarization layer with one cavity and two micro-devices according to illustrative embodiments of the present disclosure;

FIG. 10A is a partial plan view excluding the planarization layer with two cavities and two micro-devices according to illustrative embodiments of the present disclosure;

FIG. 10B is a cross section with two cavities having different depths and two micro-devices having the different thicknesses according to illustrative embodiments of the present disclosure;

FIG. 10C is a cross section with two cavities having the same depths and two micro-devices having different thicknesses extending different heights above the substrate surface according to illustrative embodiments of the present disclosure;

FIG. 11A is a cross section of a micro-device on a substrate without a cavity and without a planarization layer useful in understanding embodiments of the present disclosure;

FIG. 11B is a cross section of a micro-device on a substrate without a cavity and with an adhesive layer between the micro-device and the substrate useful in understanding embodiments of the present disclosure; and

FIG. 12 is a cross section of a micro-device on a substrate without a cavity and with a planarization layer useful in understanding embodiments of the present disclosure.

### DETAILED DESCRIPTION OF CERTAIN EMBODIMENTS

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not drawn to scale since the variation in size of various elements in the Figures is too great to permit depiction to scale.

The present disclosure provides, inter alia, micro-device structures comprising one or more micro-devices disposed on a substrate that are electrically connected, for example with a photolithographically defined wire or other electrical connection, to electrical connections, contacts, or wires on the substrate or a layer disposed on the substrate or to other micro-devices. Embodiments of the present disclosure provide structures with a reduced step height (e.g., a distance) between the top surface of a micro-device and the substrate or layer disposed on the substrate, where the top or top surface of a micro-device is a side of the micro-device opposite the substrate so that the micro-device is between the top surface and at least some portion of the substrate. Structures with such reduced step heights enable improved electrical connections between the top surface of the micro-device and electrical conductors on the substrate surface or a layer disposed on the substrate surface, for example by reducing vertical or steep edges in the structure and the need to deposit material on the vertical or steep edges. Such steep edges can be found on the side of a micro-device or the side or edge of a via. According to some embodiments, micro-devices provided as a bare die (e.g., without an integrated circuit package) can have a micro-device substrate thickness no less than five, ten, fifteen, or twenty microns with steep (e.g., substantially or effectively orthogonal to a top surface of the micro-device) edge or side of the micro-device. Where a surface of the substrate or top surface of the micro-device are effectively horizontal, such steep edges can be effectively vertical, or nearly so. Disposing material (e.g., electrically conductive material such as metal) on such steep or vertical edges can be difficult, especially where the thickness of the deposited metal (e.g., less than five microns) is less than the step height of the micro-device on the substrate (e.g., no less than five, ten, fifteen, or twenty microns, or even more). Because deposited material coverage on the steep or vertical edges can be poor, electrical connections between the top surface of the micro-device and the substrate can be likewise poor or non-existent and can therefore have a high resistance or form an electrical open (e.g., no electrical continuity between electrical contacts on the top surface of the micro-device and electrical conductors on the sub strate).

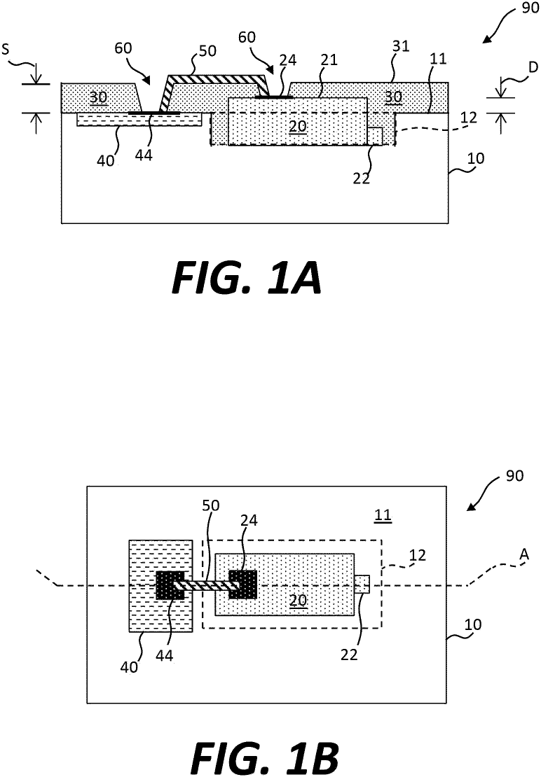

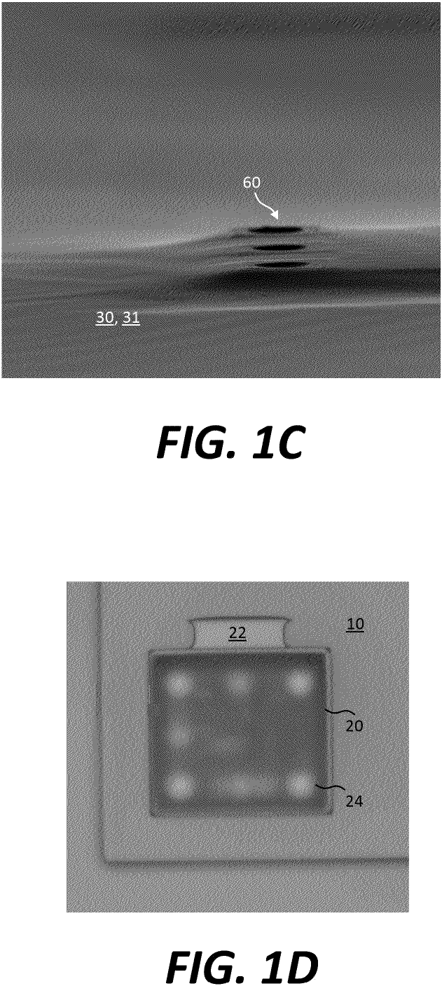

According to embodiments of the present invention and as illustrated in FIGS. 1A, 1B, 1C, and 1D, a micro-device structure 90 comprises a substrate 10 having a substrate surface 11 and a substrate contact 44 disposed on or in substrate surface 11, a cavity 12 (indicated with a dashed rectangle) disposed in substrate 10 extending to substrate surface 11, a micro-device 20 disposed in cavity 12, micro-device 20 comprising a micro-device 20 top surface 21 on or in which is disposed micro-device contact 24, a planarization layer 30 having a planarization layer surface 31 disposed over at least a portion of substrate 10, and an electrode 50 electrically connected to micro-device contact 24 and to substrate contact 44. Substrate 10 can be a target or destination substrate 10 having cavity 12 in which is disposed micro-device 20 (e.g., by micro-transfer printing micro-device 20 from a micro-device 20 source wafer to target substrate 10). Micro-device 20 can consequently comprise a tether 22 that is fractured or separated as a consequence of micro-transfer printing micro-device 20 from a micro-device source wafer to target substrate 10. Substrate contact 44 can be an electrical contact (e.g., a contact pad), a wire, an electrode, or any other electrode disposed on substrate 10 or a layer disposed on substrate 10.

As shown in the plan view of FIG. 1B excluding planarization layer 30 and the cross section of FIG. 1A taken across cross section line A of FIG. 1B, planarization layer surface 31 can extend over or above micro-device 20 and vias 60 can be provided in planarization layer 30 over micro-device contact 24 to enable electrodes 50 to contact micro-device contact 24 and substrate contact 44. Micro-device 20 can extend above substrate surface 11 a distance D and step height S indicates the largest step height in the electrical connection provided by electrode 50. A substrate circuit 40 can be formed in or on substrate 10 and electrically connected to substrate contact 44. Thus, substrate circuit 40 can be electrically connected to micro-device 20 with electrode 50 through one or more vias 60 disposed in planarization layer 30 over substrate contact 44. (For clarity of illustration, FIG. 1B omits planarization layer 30 to expose other elements of the Figure.) FIG. 1C is a perspective micro-graph of planarization layer 30 disposed on substrate 10 with vias 60 opening micro-device contacts 24 (shown in FIGS. 1A, 1B, micro-device contacts 24 are not visible in FIG. 1C.) FIG. 1D is a plan micro-graph of micro-device 20 disposed on substrate 10 with micro-device contacts 24 and fractured tether 22.

Embodiments of the present disclosure are well adapted to electrically connecting small integrated circuits (e.g., micro-devices 20) disposed on substrate 10, for example integrated circuits that are bare die and are not packaged. Such small integrated circuits can provide improved utilization of source wafers and improved circuit density and performance for heterogeneous systems comprising circuits made in different materials and native to different source wafers or source substrates. In embodiments of the present disclosure, micro-device 20 has a thickness no less than two microns, no less than five microns, no less than ten microns, no less than fifteen microns, or no less than twenty microns. Micro-device 20 can have a length or width, or both, of no greater than two hundred microns (e.g., no greater than one hundred microns, no greater than fifty microns, no greater than twenty microns, no greater than ten microns, or no greater than five microns).

According to embodiments of the present disclosure, a reduced step height between micro-device top surface 21 and substrate surface 11 can be provided by disposing micro-device 20 in cavity 12 so that micro-device top surface 21 is closer to substrate surface 11 than would be the case if micro-device 20 were placed on substrate surface 11 without cavity 12. Thus, in embodiments cavity 12 can have a depth substantially equal or relatively close to a thickness of micro-device 20, e.g., within five percent, ten percent, twenty percent, or fifty percent. In some embodiments, cavity 12 has a depth of no less than 500 nm, no less than one micron, no less than two microns, no less than five microns, no less than ten microns, no less than fifteen microns, or no less than twenty microns. Thus, according to embodiments, substrate surface 11 and micro-device top surface 21 are separated by a distance no greater than five microns (e.g., no greater than three microns, no greater than two microns, no greater than one micron, or no greater than five hundred nm) in a direction orthogonal to substrate surface 11.

In embodiments of the present disclosure, a reduced step height between micro-device top surface 21 and substrate surface 11 can be provided by providing planarization layer 30 with a thickness substantially equal to or relatively close to a height (e.g., distance D in FIG. 1A) that micro-device 20 extends or protrudes from substrate surface 11. For example, planarization layer 30 has a depth that is substantially equal to a distance between micro-device top surface 21 and substrate surface 11 or is within five percent, ten percent, twenty percent, or fifty percent of the distance. By providing a planarization layer 30 depth that matches the height (e.g., distance D in FIG. 1A) that micro-device 20 extends or protrudes from substrate surface 11, the thickness of planarization layer 30 over or on micro-device 20 is small so that vias 60 over micro-device 20 are very shallow and step height S of electrode 50 over micro-device 20 is likewise small, enabling good material deposition and electrical connection to micro-device contact 24. Thus, according to embodiments of the present disclosure, planarization layer 30 has a thickness over substrate surface 11 (or a layer disposed on substrate surface 11) of no greater than one micron (e.g., no greater than ten nm, no greater than twenty nm, no greater than thirty nm, no greater than fifty nm, no greater than sixty nm, no greater than seventy-five nm, no greater than one hundred nm, no greater than two hundred fifty nm, or no greater than five hundred nm). Where micro-device 20 protrudes above substrate surface 11, via 60 opening substrate contact 44 will have a greater step height S than via 60 opening micro-device contact 24 but is still smaller than would be the case if a thicker planarization layer 30 was coated over substrate surface 11, enabling good material deposition and electrical connection to substrate contact 44.

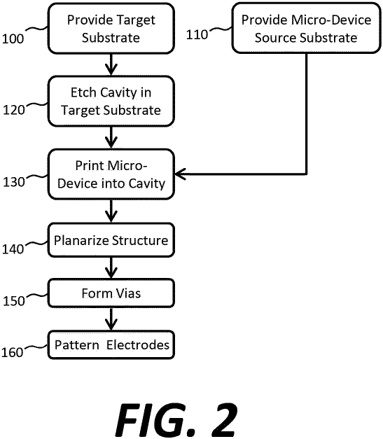

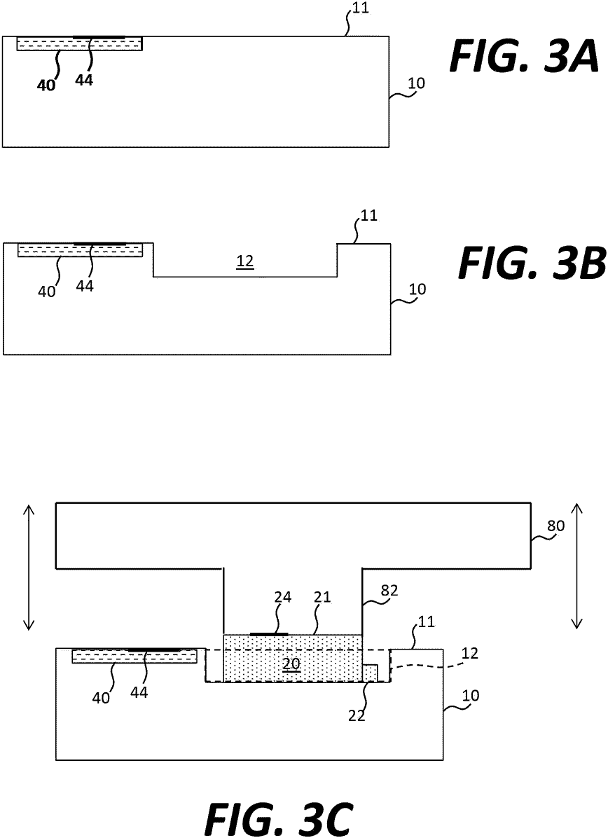

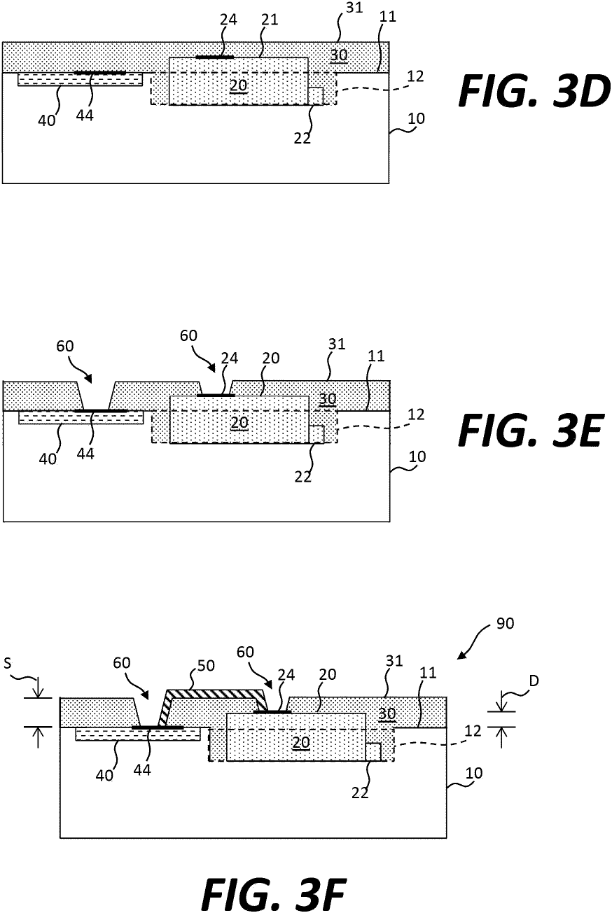

According to embodiments of the present disclosure and as illustrated in the flow diagram of FIG. 2 and the successive cross sections of FIGS. 3A-3G, a method of making a micro-device structure 90 comprises providing a substrate 10 having a substrate surface 11 in step 100. A substrate contact 44 can be disposed on or in substrate surface 11 and a substrate circuit 40 electrically connected to substrate contact 44 can be disposed on or in substrate surface 11, as shown in FIG. 3A. A cavity 12 can be disposed in substrate 10 that extends to substrate surface 11 (e.g., by etching), in step 120 and as shown in FIG. 3B. (In some embodiments, substrate contact 44, substrate circuit 40, and cavity 12 can be provided in step 100 and step 120 is optional.) Cavity 12 can be made before, during, or after substrate circuit 40 or substrate contact 44 is formed. Substrate 10 can be any suitable substrate 10 having substrate surface 11 suitable for micro-transfer printing and photolithographic processing, for example a glass or polymer substrate as found in the display and photolithographic industries. Substrate circuit 40, substrate contact 44, and cavity 12 can be constructed on or in substrate surface 11 using photolithographic methods and materials such as are used in the display and integrated circuit industries. A micro-device source wafer (not shown in the Figures) is provided in step 110 with one or more micro-devices 20 disposed on or in the micro-device source wafer. Micro-device source wafer can comprise sacrificial portions separated by anchors and micro-devices 20 can be disposed directly and completely over the sacrificial portions and physically connected to anchors by tethers 22 so that micro-devices 20 can be transfer printed (e.g., micro-transfer printed) from micro-device source wafer to substrate 10. Such micro-device source wafers can be constructed using photolithographic materials and methods, for example silicon wafers or semiconductor-on-insulator wafers.

In step 130 and as shown in FIG. 3C, one or more micro-devices 20 are micro-transfer printed from the micro-device source wafer into cavity 12 of substrate 10, for example with a stamp 80 such as a PDMS stamp 80 having stamp posts 82 temporarily adhered to micro-device 20, fracturing or separating tether 22 in the process. In step 140 and as shown in FIG. 3D, a planarization layer 30 is disposed at least partly over substrate 10. In some embodiments, planarization layer 30 extends over substantially extends over substrate surface 11 and micro-device 20 and optionally within cavity 12. Planarization layer 30 can be an organic material deposited by spin coating or spray coating, for example benzocyclobutene (BCB), Intervia, an epoxy, or a photo-resist. Planarization layer 30 material can be curable, e.g., with heat or by exposure to electromagnetic radiation (e.g., ultraviolet radiation). Planarization layer 30 can at least partially planarize substrate 10, micro-device 20, and cavity 12, for example forming a surface that is more planar and has less topography than substrate 10, micro-device 20, and cavity 12 in the absence of planarization layer 30.

If planarization layer 30 extends over micro-device contact 24, a via 60 can be formed over micro-device contact 24 and if planarization layer 30 extends over substrate contact 44, a via 60 can be formed over substrate contact 44 in step 150 and as shown in FIG. 3E. In step 160 and as illustrated in FIG. 3F, an electrode 50 is patterned over substrate 10 and at least partially over or on planarization layer 30 in electrical contact with micro-device contact 24. Vias 60 and electrodes 50 can be formed using photolithographic methods and materials. In some embodiments, electrode 50 is in electrical contact with substrate contact 44. According to embodiments of the present disclosure, a step height S between a surface 31 of planarization layer 30 and micro-device contact 24 or substrate contact 44 (e.g., a step height of electrode 50) is less than a corresponding step height if micro-device 20 was not disposed in cavity 12, thus enabling improved conductive material deposition over the vertical or steep edges of micro-device 20 or vias 60.

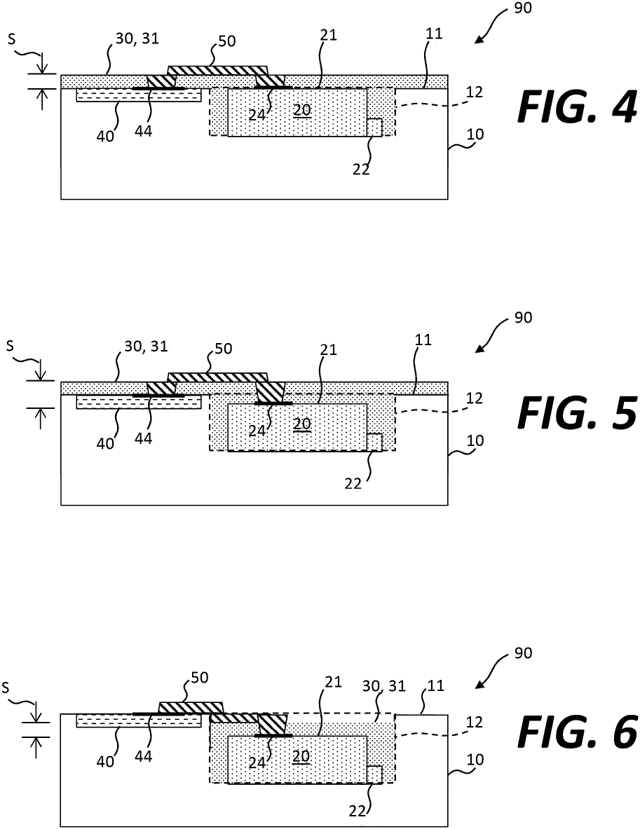

According to embodiments of the present disclosure, cavity 12 can have a depth substantially equal to or within five percent, ten percent, twenty percent, or fifty percent of the thickness of micro-device 20. FIGS. 1A and 3F illustrate embodiments in which cavity 12 has a depth less than a thickness of micro-device 20. FIG. 4 shows micro-device 20 with a thickness substantially equal to the depth of cavity 12 and FIG. 5 illustrates embodiments in which cavity 12 has a depth greater than a thickness of micro-device 20. In all of these embodiments, the largest step height S between planarization layer surface 31 and micro-device contact 24 or substrate contact 44 is less than would be the case if micro-device 20 was not disposed in cavity 12.

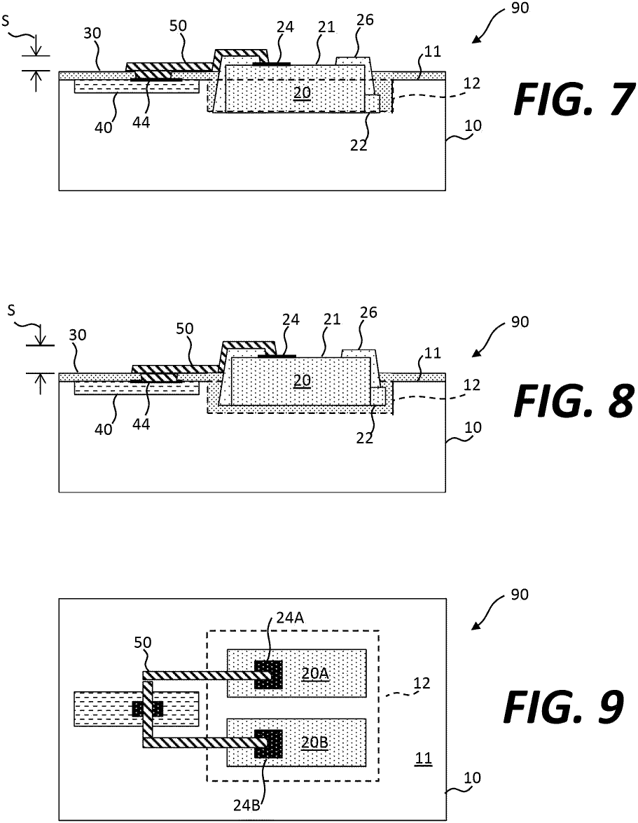

According to embodiments of the present disclosure and as illustrated in FIGS. 1A and 3D-3F, planarization layer 30 can be disposed at least partly in cavity 12. FIG. 6 illustrates embodiments in which planarization layer 30 is disposed mostly or exclusively in cavity 12. FIG. 7 illustrates embodiments in which planarization layer 30 is disposed in cavity 12 and at least partly over substrate surface 11 but not over micro-device top surface 21. Dielectric structures 26 can insulate the edges of micro-device 20 from electrode 50 in the absence of planarization layer 30. Embodiments of the present disclosure comprise planarizing substrate 10 with planarization layer 30 after micro-transfer printing one or more micro-devices 20 from a micro-device source wafer into cavity 12 in substrate 10.

FIG. 8 illustrates embodiments in which planarization layer 30 is disposed over substrate surface 11 before micro-device 20 is disposed in cavity 12 so that micro-device 20 is disposed at least partly on planarization layer 30 in cavity 12. Embodiments of the present disclosure comprise planarizing substrate 10 with planarization layer 30 before micro-transfer printing one or more micro-devices 20 from a micro-device source wafer into cavity 12 in substrate 10.

Planarization layer 30 can be disposed at least partially on a sidewall of cavity 12, for example as shown in FIG. 1A and FIG. 8. Planarization layer 30 can have a thickness no greater than a few nanometers, for example, five, ten, twenty, fifty, seventy, or one hundred nanometers. In some embodiments, planarization layer 30 can have a thickness no greater than one, two, five, ten, twenty, fifty, or one hundred microns. In some embodiments, planarization layer 30 has a thickness that is no greater than a thickness of micro-device 20, no greater than a difference between a depth of cavity 12 and thickness of micro-device 20, or no greater than one half, one, two, or five microns than the difference. Dielectric structures 26 can insulate the edges of micro-device 20 from electrode 50 in the absence of planarization layer 30. In such embodiments, step height S is still reduced compared to embodiments in which micro-device 20 is not disposed in cavity 12 or in which planarization layer 30 is absent.

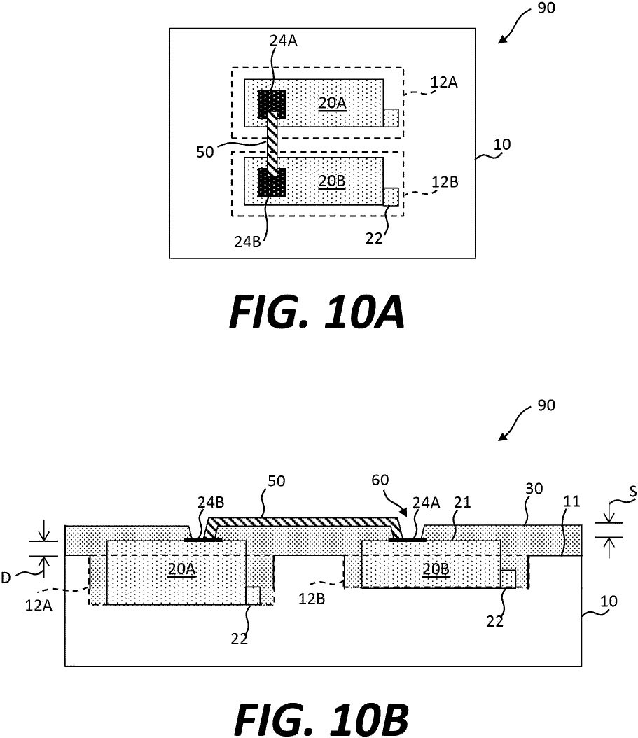

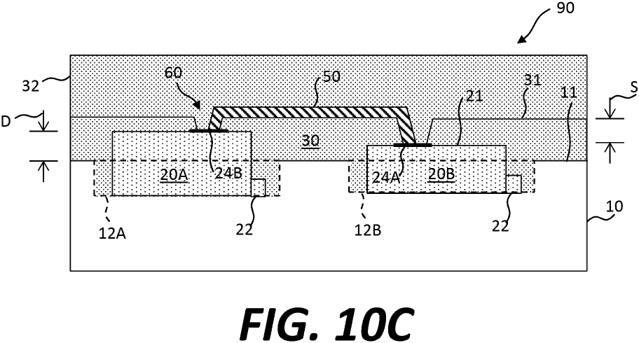

According to some embodiments of the present disclosure and as illustrated in FIG. 9, two or more micro-devices 20 can be disposed in a common same cavity 12. Electrode 50 can electrically connect micro-device contacts 24 of the two or more micro-devices 20, can electrically connect substrate contact 44 to all or a subset of the two or more micro-devices 20, or both. As shown in FIG. 10A, electrode 50 directly connects two or more micro-devices 20 and, as shown in FIG. 10B, extends over planarization layer 30 but does not pass through a via 60 to substrate surface 11, e.g., as in FIG. 9. For clarity of illustration, FIGS. 9 and 10A omit planarization layer 30 and vias 60. Thus, according to some embodiments of the present disclosure and as shown in FIG. 9, micro-device 20 is a first micro-device 20A, micro-device contact 24 is a first micro-device contact 24A and micro-device structures 90 can comprise a second micro-device 20B disposed in cavity 12. Second micro-device 20B can comprise a second micro-device contact 24B, and electrode 50 can electrically connect first micro-device contact 24A to second micro-device contact 24B.

According to some embodiments of the present disclosure and as illustrated in FIGS. 10A and 10B, two or more micro-devices 20 can each be disposed in a different cavity 12. As shown in FIGS. 10A and 10B, first micro-device 20A with first micro-device contact 24A is disposed in first cavity 12A and second micro-device 20B with second micro-device contact 24B is disposed in second cavity 12B. Electrode 50 electrically connects first micro-device contact 24A to second micro-device contact 24B. Thus, according to embodiments, micro-device 20 is a first micro-device 20A, micro-device contact 24 is a first micro-device contact 24A, cavity 12 is a first cavity 12A and micro-device structures 90 can comprise a second micro-device 20B disposed in a second cavity 12B in substrate 10. Second micro-device 20B comprises a second micro-device contact 24B and electrode 50 electrically connects first micro-device contact 24A to second micro-device contact 24B. Electrode 50 can pass through vias 60 and on or over planarization layer 30. In some embodiments, electrode 50 can pass through a via 60 to a substrate contact 44 (e.g., as shown in FIG. 9) or does not extend to substrate surface 11 (e.g., as shown in FIGS. 10A and 10B). Cavity 12A can have a different depth than cavity 12B or first micro-device 20A can have a different thickness than second micro-device 20B, as shown in FIG. 10B. Such different cavity 12 depths can accommodate micro-devices 20 with different thicknesses to enable reduced step heights for both micro-devices 20 by matching micro-device 20 thickness to cavity 12 depth and thereby reducing step heights in micro-device structure 90. FIG. 10C illustrates embodiments with different-thickness micro-devices 20 with cavities 12 having a same depth.

Thus, according to embodiments of the present disclosure, a micro-device structure 90 comprises a substrate 10 having a substrate surface 11, one or more cavities 12 disposed in substrate 10, each of the cavities 12 extending to substrate surface 11, two or more micro-devices 20, at least one micro-device 20 disposed in each of the one or more cavities 12, each micro-device 20 comprising a micro-device contact 24, and an electrode 50 electrically connecting at least a first micro-device contact 24A of a first micro-device 20A and a second micro-device contact 24B of a second micro-device 20B. As shown in FIG. 9, two or more micro-devices 20 can be disposed in one cavity 12. As shown in FIGS. 10A and 10B, the one or more cavities 12 can comprise at least two cavities 12 with a micro-device 20 disposed in each of the at least two cavities 12. As shown in FIG. 10C, in some embodiments, a first cavity 12A of the one or more cavities 12 extends a first distance into substrate 10, a second cavity 12B of the one or more cavities 12 extends a second distance into substrate 10, and the first distance is different from the second distance so that first and second cavities 12A, 12B have different depths. In some embodiments, a first micro-device 20A of the two or more micro-devices 20 has a first thickness, a second micro-device 20B of the two or more micro-devices 20 has a second thickness, and the first thickness is different from the second thickness so that first and second micro-devices 20A, 20B have different depths. A planarization layer 30 can be disposed over at least a portion of substrate 10, in cavity 12, or on or over micro-device 20. A substrate contact 44 can be disposed on or in substrate surface 11 and electrode 50 can be electrically connected to substrate contact 44. In embodiments of the present disclosure, a top surface 21 of micro-device 20 can be separated from substrate surface 11 by a distance no greater than five microns, no greater than three microns, no greater than two microns, no greater than one micron, or no greater than five hundred nm in a direction orthogonal to substrate surface 11. Micro-device 20 can comprise a separated or fractured tether 22.

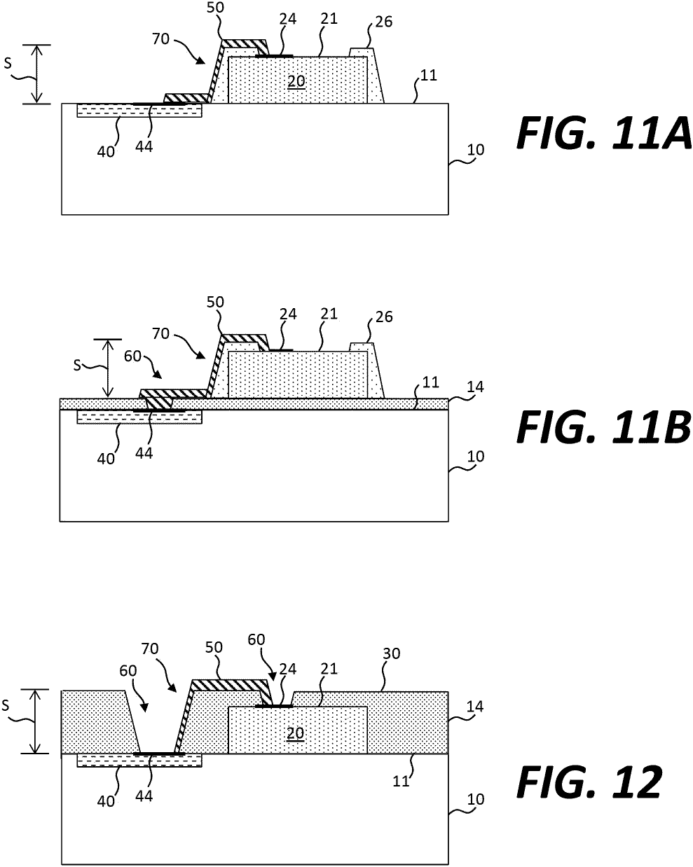

FIGS. 11A, 11B, and 12 illustrate structures that do not use cavities 12. As shown in FIG. 11A, a micro-device 20 disposed on substrate surface 11 of substrate 10 with a substrate contact 24 electrically connected with electrode 50 to substrate contact 44 on substrate 10 has a relatively large step height S. Similarly, as shown in FIG. 11B, a micro-device 20 disposed on a relatively thin adhesive layer 14 on substrate surface 11 of substrate 10 with a substrate contact 24 electrically connected with electrode 50 to substrate contact 44 through via 60 on substrate 10 also has a relatively large step height S. As shown in FIG. 12, a micro-device 20 disposed on a relatively thick planarizing adhesive layer 14 on substrate surface 11 of substrate 10 with a substrate contact 24 electrically connected with electrode 50 to substrate contact 44 through via 60 on substrate 10 has a relatively large step height S. The relatively large step height S (e.g., no less than five or no less than ten microns) can have relatively poor conductive material coverage 70 for electrode 50, reducing electrode 50 conductivity, as shown in FIG. 11A-12. Thus, embodiments of the present disclosure comprising micro-device 20 disposed in cavity 12 have a reduced step height S and improved electrical connections.

Micro-device 20 can be or can include, for example, any one or more of an electronic component, a piezoelectric device, an integrated circuit, an electromechanical filter, an acoustic resonator, an antenna, a micro-heater, a micro-fluidic structure for containing and constraining fluids, a micro-mechanical device, and a power source, for example a piezo-electric power source. Micro-device(s) 20 can be electronic, optical, or optoelectronic devices that can be electrically, optically, or both electrically and optically interconnected to other micro-devices 20 or substrate circuit 40. Although many figures presented herein often illustrate a single micro-device 20, one of ordinary skill in the art will appreciate that there will generally be many such micro-devices 20 or cavities 12 (e.g., in a two-dimensional array). According to some embodiments, micro-device 20 has a thickness less than 1 mm (e.g., no greater than 500, 200, 100, 50, 20, 10, 5, 1, or 0.5 microns). According to some embodiments, micro-device 20 has a length or width less than 1 mm (e.g., no greater than 500, 200, 100, 50, 20, or 10 microns).

A micro-device 20 can be any device that has at least one dimension that is in the micron range, for example having a planar extent from 2 microns by 5 microns to 200 microns by 500 microns (e.g., an extent of 2 microns by 5 microns, 20 microns by 50 microns, or 200 microns by 500 microns) and, optionally, a thickness of from 200 nm to 200 microns (e.g., at least or no greater than 2 microns, 20 microns, or 200 microns). In some embodiments, micro-device 20 has a dimension as large as, or larger than 5 mm. Micro-device 20 can have any suitable aspect ratio or size in any dimension and any useful shape, for example a rectangular area or cross section. Micro-device 20 can be non-native to substrate 10. According to embodiments of the present disclosure, cavity 12 has a length and width over substrate 10 that is only slightly larger than a length and width of micro-device 20, for example 500 nm, one micron, two microns, three microns, five microns, ten microns, or twenty microns larger in length or width, or both length and width. Similarly, cavity 12 can have a thickness that is only slightly larger or smaller than a thickness of micro-device 20, for example no greater than twenty microns, no greater than ten microns, no greater than five microns, no greater than two microns, no greater than one micron, or no greater than 50 nm. Providing a cavity 12 with a depth approximately equal to a thickness of micro-device 20 reduces a step height S from micro-device top surface 21 and a substrate surface 11 of substrate 10. Providing a cavity 12 with an area over substrate surface 11 that is only slightly larger than an area of micro-device 20 likewise reduces the topology (changes in substrate surface 11 height with respect to a plane), improving the coating of an electrical conductor over substrate surface 11 and micro-device 20. According to embodiments of the present disclosure, micro-devices 20 can be micro-transfer printed into cavities 12 that have an area that is only a few, or less than one, microns larger in length and width than an area of the micro-devices 20. Other conventional methods such as pick-and-place used to dispose surface mount devices on a target substrate can be too inaccurate or too imprecise to effectively place micro-devices 20 into such cavities 12 and cannot readily dispose micro-devices with a length and width less than 200 microns.

According to some embodiments, micro-device 20 can be disposed over and native to a source wafer (e.g., a source substrate). A source wafer can comprise a sacrificial layer comprising anchor portions laterally separated by sacrificial portions in a direction parallel to a surface of the source wafer. Anchor portions can be a part of source wafer or a structure disposed on the source wafer. Micro-devices 20 can each be disposed over a sacrificial portion and physically connected by a tether 22 to an anchor portion. Sacrificial portions can be etched to form a gap between a micro-device 20 and the source wafer so that micro-devices 20 can be transfer printed from the source wafer to target substrate 10, thereby fracturing or separating tethers 22.

In some embodiments of the present disclosure, micro-devices 20 are small integrated circuits, which may be referred to as chiplets, having a thin micro-device substrate with at least one of (i) a thickness of only a few microns, for example less than or equal to 25 microns, less than or equal to 15 microns, or less than or equal to 10 microns, (ii) a width of 5-1000 microns (e.g., 5-10 microns, 10-50 microns, 50-100 microns, or 100-1000 microns), and (iii) a length of 5-1000 microns (e.g., 5-10 microns, 10-50 microns, 50-100 microns, or 100-1000 microns). Such chiplets can be made in a native source semiconductor wafer (e.g., a silicon wafer) having a process side and a back side used to handle and transport the source wafer using lithographic processes. Micro-devices 20 can be formed using lithographic processes in an active layer on or in the process side of a micro-device source wafer. Methods of forming such structures are described, for example, in U.S. Pat. 8,889,485. According to some embodiments of the present disclosure, source wafers can be provided with micro-devices 20, sacrificial layer (a release layer), sacrificial portions, and tethers 22 already formed, or they can be constructed as part of a process in accordance with certain embodiments of the present disclosure.

In certain embodiments, micro-devices 20 can be constructed using foundry fabrication processes used in the art. Layers of materials can be used, including materials such as metals, oxides, nitrides and other materials used in the integrated-circuit art. Micro-devices 20 can have different sizes, for example, less than 1000 square microns or less than 10,000 square microns, less than 100,000 square microns, or less than 1 square mm, or larger. Micro-devices 20 can have, for example, at least one of a length, a width, and a thickness of no greater than 500 microns (e.g., no greater than 250 microns, no greater than 100 microns, no greater than 50 microns, no greater than 25 microns, or no greater than 10 microns). Micro-devices 20 can have variable aspect ratios, for example at least 1:1, at least 2:1, at least 5:1, or at least 10:1. Micro-devices 20 can be rectangular or can have other shapes.

Tethers 22 can comprise any suitable tether material and can incorporate one or more layers, for example one or more layers similar to or the same as those layer(s) of micro-device 20, for example comprising electrode material, dielectric(s), or encapsulation layer(s), including resins, silicon oxides, silicon nitrides, or semiconductors. Tethers 22 can be constructed be depositing (e.g., by evaporation or sputtering) material such as oxide, nitride, metal, polymer, or semiconductor material, and patterning the material, for example using photolithographic methods and materials, such as pattern-wise exposed and etched photoresist.

Micro-device source wafers (e.g., source substrates) can be any useful substrate with a surface suitable for forming or having patterned sacrificial layers, sacrificial portions, anchor portions, and forming or disposing micro-devices 20. Source wafers can comprise glass, ceramic, polymer, metal, quartz, or semiconductors, for example as found in the integrated circuit or display industries. A sacrificial portion can be a designated portion of a sacrificial layer, for example an anisotropically etchable portion, for example designated by virtue of etchant applied to the source wafer is exposed to it relative to other portions of the source wafer, or a differentially etchable material from sacrificial layer, for example a buried oxide or nitride layer, such as silicon dioxide. A surface of the source wafer can be substantially planar and suitable for photolithographic processing, for example as found in the integrated circuit or MEMs art. Source wafers can be chosen, for example, based on desirable growth characteristics (e.g., lattice constant, crystal structure, or crystallographic orientation) for growing one or more materials thereon. In some embodiments of the present disclosure, the source wafer is anisotropically etchable. For example, a source wafer can be a monocrystalline silicon substrate with a {100} orientation. An anisotropically etchable material etches at different rates in different crystallographic directions, due to reactivities of different crystallographic planes to a given etchant. For example, potassium hydroxide (KOH) displays an etch rate selectivity 400 times higher in silicon [100] crystal directions than in silicon [111] directions. In particular, silicon { 100} is a readily available, relatively lower cost monocrystalline silicon material. Moreover, in some embodiments, micro-devices 20 made on or in a silicon { 100} crystal structure can have less stress and therefore less device bowing after release.

As is understood by those skilled in the art, the terms “over” and “under” are relative terms and can be interchanged in reference to different orientations of the layers, elements, and substrates included in the present disclosure. For example, a first layer on a second layer, in some implementations means a first layer directly on and in contact with a second layer. In other implementations, a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as operability is maintained. Moreover, two or more steps or actions in some circumstances can be conducted simultaneously. The disclosure has been described in detail with particular reference to certain embodiments thereof, but it will be understood that variations and modifications can be effected within the spirit and scope of the claimed invention.

### PARTS LIST

A cross section
D distance
S step height
10 substrate / target substrate
11 substrate surface
12 cavity
12A first cavity
12B second cavity
14 adhesive layer
20 micro-device
20A first micro-device
20B second micro-device
21 micro-device top surface
22 tether
24 micro-device contact
24A micro-device contact
24B micro-device contact
26 dielectric structure
30 planarization layer
31 planarization layer surface
40 substrate circuit
44 substrate contact
50 electrode
60 via
70 poor electrode coverage
80 stamp
82 stamp post
90 micro-device structure
100 provide target substrate step
110 provide micro-device source wafer step
120 etch cavity in target substrate step
130 print micro-device into cavity step
140 planarize structure step
150 pattern vias step
160 form electrodes step

1. A micro-device structure, comprising:
a substrate having a substrate surface;
a cavity extending into the substrate from the substrate surface;
a micro-device disposed in the cavity, the micro-device comprising a micro-device contact;
a planarization layer disposed over at least a portion of the substrate; and
an electrode disposed at least partially on the planarization layer and electrically connected to the micro-device contact.

2. The micro-device structure of claim 1, comprising a substrate contact disposed on or in the substrate surface and wherein the electrode is electrically connected to the substrate contact.

3. The micro-device structure of claim 1, wherein the micro-device comprises a separated or broken tether.

4. The micro-device structure of claim 1, wherein the planarization layer is disposed at least partly in the cavity.

5. The micro-device structure of claim 4, wherein the micro-device is disposed at least partly on at least a portion of the planarization layer in the cavity.

6. The micro-device structure of claim 1, (i) wherein the micro-device has a thickness no greater than twenty microns , (ii) wherein the cavity has a depth of no greater than twenty microns , (iii) wherein the planarization layer has a thickness over the substrate surface of no greater than one micron , or (iv) any combination of (i), (ii), and (iii).

7. The micro-device structure of claim 1, wherein the substrate surface and a top surface of the micro-device are separated by a distance no greater than five microns in a direction orthogonal to the substrate surface.

8. The micro-device structure of claim 1, wherein the substrate surface and a top surface of the micro-device are separated by a distance less than a thickness of the micro-device.

9. The micro-device structure of claim 1, wherein the substrate contact is an electrode disposed on the substrate.

10. The micro-device structure of claim 1, wherein the micro-device is a first micro-device, the micro-device contact is a first micro-device contact and the micro-device structure comprises a second micro-device disposed in the cavity, the second micro-device comprising a second micro-device contact, and wherein the electrode electrically connects the first micro-device contact to the second micro-device contact.

11. The micro-device structure of claim 1, wherein the micro-device is a first micro-device, the micro-device contact is a first micro-device contact, the cavity is a first cavity, and the micro-device structure comprises a second micro-device disposed in a second cavity extending into the substrate from the substrate surface, the second micro-device comprising a second micro-device contact, and wherein the electrode electrically connects the first micro-device contact to the second micro-device contact.

12. A micro-device structure, comprising:
a substrate having a substrate surface;
one or more cavities extending into the substrate from the substrate surface;
micro-devices, at least one of the micro-devices disposed in each of the one or more cavities, each of the micro-devices comprising a micro-device contact; and
an electrode electrically connecting at least a first micro-device contact of a first one of the micro-devices and a second micro-device contact of a second one of the micro-devices.

13. The micro-device structure of claim 12, wherein (i) the one or more cavities comprises at least two cavities, (ii) two or more of the micro-devices are disposed in one of the one or more cavities, or both (i) and (ii).

14. The micro-device structure of claim 12, comprising a planarization layer disposed over at least a portion of the substrate.

15. The micro-device structure of claim 12, wherein a first cavity of the one or more cavities extends a first distance into the substrate, a second cavity of the one or more cavities extends a second distance into the substrate, and the first distance is different from the second distance.

16. The micro-device structure of claim 12, wherein a first micro-device of the micro-devices has a first thickness, a second micro-device of the micro-devices has a second thickness, and the first thickness is different from the second thickness.

17. The micro-device structure of claim 12, comprising a substrate contact disposed on or in the substrate surface and wherein the electrode is electrically connected to the substrate contact.

18. The micro-device structure of claim 12, wherein a top surface of the micro-device is separated from the substrate surface by a distance no greater than five microns, no greater than three microns, no greater than two microns, no greater than one micron, or no greater than five hundred nm in a direction orthogonal to the substrate surface.

19. The micro-device structure of claim 12, wherein the micro-devices each comprise a separated or broken tether.

20. The micro-device structure of claim 12, wherein ones of the micro-devices (i) have different functionalities, (ii) comprise different materials , or (iii) both (i) and (ii).

21-32. (canceled)
